(19) United States
(12) Patent Application Publication
(10) Pub. No.: US 2008/0296680 A1
(43) Pub. Date: Dec. 4, 2008

(54) METHOD OF MAKING AN INTEGRATED CIRCUIT INCLUDING DOPING A FIN

(75) Inventors: Matthias Goldbach, Dresden (DE); Stefan Jakschik, Leuven (BE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/755,137

(22) Filed: May 30, 2007

(51) Int. Cl. H01L 29/786; H01L 21/336; H01L 21/425

(52) U.S. Cl. 257/347; 438/164; 438/527; 257/E21.473; 257/E21.411; 257/E29.273

(57) ABSTRACT

A method of making an integrated circuit including doping a fin is disclosed. The method includes providing a substrate having at least one fin of a semiconductor material and carrying out a gas-phase doping of the at least one fin.

### BACKGROUND

Different types of transistors may be formed in a semiconductor material. One type is the Fin-Field Effect Transistor. The active region of a Fin-FET includes a section having the shape of a ridge. A predetermined portion of that section is surrounded by the gate insulating material and the gate electrode. Thus the current path (the channel) is controlled by the gate electrode from two or more sides.

Fin-FETs may be manufactured as transistors in a semiconductor material on a SOI-substrate. Thus the active region is vertically limited by the underlying insulating material. Another possibility to form a Fin-FET includes defining an active region in a bulk semiconductor material, wherein the fin-portion, that is that section of the active area that has the shape of a ridge forms a part of the semiconductor material and is laterally delimited by an insulating material.

While defining the active region and forming the gate insulating material and the gate electrode are well known processes in manufacturing a Fin-FET, defining the source and the drain region in the active region is a process causing several difficulties. Especially methods for bringing in dopants into the fin-portion are desired, which do not cause lattice defects in the semiconductor material and which are not affected by small spaces between neighboring fin-portions.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1A illustrates a flow diagram of a method of making an integrated circuit including doping a fin;

FIG. 1B illustrates a flow diagram of a method of manufacturing a transistor;

FIG. 2 illustrates a plan view on an embodiment of a transistor;

FIG. 3A illustrates a perspective view of an embodiment of the transistor of FIG. 2;

FIG. 3B illustrates a schematic cross sectional view through the transistor of FIG. 3A;

FIG. 4A illustrates a perspective view of another embodiment of the transistor of FIG. 2;

FIG. 4B illustrates a schematic cross sectional view through the transistor of FIG. 4A;

FIGS. 5A to 5C illustrate plan views on embodiments of a transistor at different processing steps of the described method;

FIG. 6 illustrates a plan view on another embodiment of a transistor;

FIG. 7 illustrates a flow diagram of a method of manufacturing an integrated circuit;

FIG. 8 illustrates a plan view on an embodiment of an integrated circuit;

FIGS. 9A and 9B illustrate plan views on an embodiment of an integrated circuit at different processing steps of the described method.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

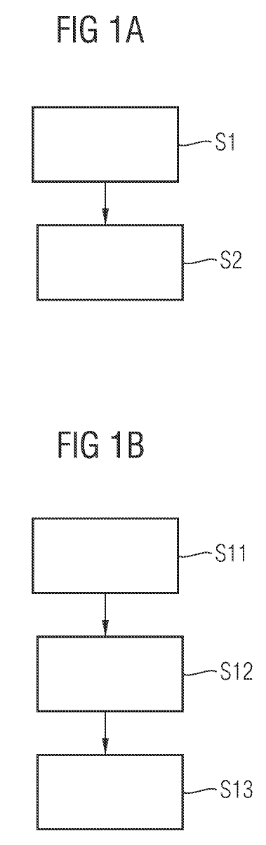

FIG. 1A illustrates a flow diagram of an embodiment of a method of making an integrated circuit including doping a fin. First, a substrate is provided, having at least one fin of a semiconductor material (S1). The substrate may be a SOI-substrate or a SOS-substrate or may be a conventional semiconductor substrate. As by way of example, the semiconductor material may be a semiconductor layer of a layer stack comprised by the substrate or may be a part of the bulk material of the semiconductor substrate. The fin is a portion of the semiconductor material having a small width. The width of the fin may, by way of example, be smaller than or equal to 50 nm. The width of the fin may be larger than or equal to 10 nm. A gas-phase doping is carried out for bringing in dopants of a predetermined species into the semiconductor material of the fin (S2).

In one embodiment, the method of doping a fin may further include providing a first cover layer over a predetermined section of the fin before carrying out the gas-phase doping. The first cover layer prevents the semiconductor material of the predetermined section from being doped during the gas-phase doping or retards the entry of dopants into the semiconductor material of the predetermined section from the gas phase. The first cover layer may include any material, which is suited for preventing the predetermined section from an undesired doping during subsequent gas-phase doping. The first cover layer may for instance include Al₂O₃, SiN or TiN.

The dopant concentration within the semiconductor material of the fin may be higher than 1·10²⁰ cm⁻³ after carrying out the gas-phase doping and may be defined by the process parameters of the gas-phase doping, like for instance gas pressure, temperature and time.

The difference between the maximum and the minimum of the dopant concentration within the semiconductor material of the fin not covered by a first cover layer may be less than or equal to factor 2. Accordingly, a very good homogeneity of dopant concentration may be accomplished.

In one embodiment, the described method may further include providing a second cover layer over the fin outside the predetermined section. The second cover layer may include any material, which is suited to retard the entry of dopants into the semiconductor material from the gas phase. It may include the same or other materials than the first cover layer. The diffusion coefficient of the dopants through the second cover layer is higher than the diffusion coefficient of the dopants through the first cover layer. This may be achieved by providing the second cover layer with a smaller thickness than the thickness of the first cover layer over the predetermined section, for instance if the same materials for the first and the second cover layer are used, or by using different materials for the first and the second cover layer. The second cover layer improves the homogeneity of the dopant concentration within the semiconductor material of the fin and allows to better control the amount of dopants within the semiconductor material.

In one embodiment, the described method may further include creating lattice imperfections within the fin before carrying out the gas-phase doping. The lattice imperfections enhance the diffusion of dopants within the semiconductor material. If lattice imperfections are created in the fin only outside a predetermined section covered by a cover layer, the difference between the enhanced diffusion outside the predetermined section and the intrinsic diffusion within the predetermined section limits the diffusion of dopants into the predetermined section, thus allowing to control the spatial distribution of the dopants.

FIG. 1B illustrates a flow diagram of an embodiment of a method for manufacturing a transistor. First an active region is defined in a semiconductor material (S11). The semiconductor material may be a part of a SOI-substrate or a SOS-substrate or may be a part of a conventional semiconductor substrate. As by way of example, the semiconductor material may be a semiconductor layer of a layer stack comprised by a substrate or may be a part of the bulk material of the semiconductor substrate. The substrate or a part of it or the semiconductor material itself may be patterned. The semiconductor material may for instance be silicon. The substrate may for instance include memory cells or other devices. Furthermore, it may include layers of different materials, like for instance semiconductor material, metals, insulating materials, organic materials or others.

The active region may be defined by patterning the semiconductor material, like for instance by etching. The active region includes a section having the shape of a ridge. This section is also called fin-portion. In the fin-portion, a current path or channel between a source region and a drain region of the transistor is to be formed, wherein the conductivity of the current path may be controlled by a gate electrode.

A first predetermined portion of the fin-portion is covered with a first cover layer (S12). The first predetermined portion includes at least that portion of the fin-portion, in which the current path is to be formed and to be controlled by the gate electrode of the transistor. The first cover layer may, for instance, include a gate insulating layer adjacent to the semiconductor material and a gate electrode adjacent to the gate insulating material. Nevertheless, the first cover layer may include any other material, which is suited for preventing an undesired doping of the first predetermined portion during subsequent processing. The first cover layer may for instance include Al₂O₃, SiN or TiN. Furthermore, the first cover layer may include a gate insulating layer, the gate electrode and a covering layer suited for preventing an undesired doping of the gate electrode during subsequent processing. The first cover layer covers the side portions and the upper portion of the first predetermined portion of the fin-portion. The first cover layer may be formed by any suited process, like for instance a CVD (Chemical vapour deposition) process or an ALD (Atomic layer deposition) process.

Next a source region and a drain region in the active region are provided, wherein this process includes carrying out a gas-phase doping process (S13). Gas-phase doping is a doping process wherein dopants are provided from a gaseous source and diffuse into a substrate, in this case the semiconductor material of the active region. At least that portions of the source and the drain region formed within the fin-portion are provided by the gas-phase doping. Portions of the source and the drain region outside the fin-portion may be provided using other doping processes, like for instance ion-implantation or selective doped epitaxy, but may be provided using gas-phase doping as well.

Accordingly, source and drain regions may be provided without destroying or deteriorating the lattice structure of the semiconductor material of the active region in the fin-portion. Furthermore, the doping process is not affected by geometrical limitations like for instance a plurality of neighboring fin-portions arranged with a small distance to each other, like it is the case for doping by ion implantation, for instance through shadowing effects.

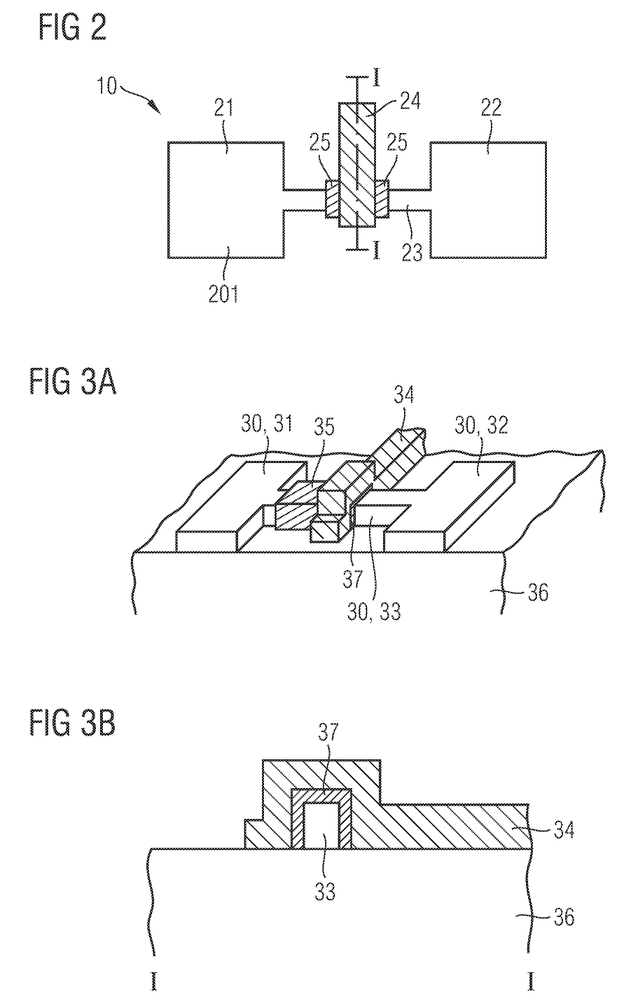

FIG. 2 illustrates a plan view on an embodiment of a transistor 10. The transistor 10 includes an active region 201 formed in a semiconductor material 20 and having a first and a second doped portion 21, 22 and a section 23. The section 23 of the active region, which includes the channel, is arranged between the first and the second doped portion 21, 22 and has the shape of a ridge or a fin. The section 23 is called the fin-like portion of the active area. The first and/or the second doped portion 21, 22 may extend into the section 23. The width of the first doped portion 21, the second doped portion 22 and the section 23 may be different, for instance the widths of the first and the second doped portion may be larger than the width of the section 23 as illustrated in FIG. 2. Nevertheless, the width of the first and/or the second doped portion 21, 22 may be the same as the width of the section 23.

A gate electrode 24 is formed above a first predetermined portion of the fin-like portion 23. The gate electrode 24 may include an electrically conductive material, like for instance a heavily doped semiconductor material or a metal, or a layer stack of electrically conductive materials. Spacers 25 formed of an insulating material may be arranged at the side portions of the gate electrode 24. The spacer 25 may insulate the electrically conductive material of the gate electrode 24 from the fin-like portion 23 at side portions, and an insulating material may be arranged between the fin-like portion 23 and the gate electrode 24, wherein the insulating material may form the gate insulator of the transistor 10. The gate electrode 24 is configured to control the conductivity of the semiconductor material 20 in a channel region of the transistor 10 arranged in the first predetermined portion of the section 23. The channel region is arranged between a source and a drain region of the transistor 10, wherein the source region includes the first or the second doped region 21, 22 and wherein the drain region includes the other doped region 21, 22. The source and the drain region may extend into the fin-like portion 23 except the first predetermined portion covered by the gate electrode 24.

Nevertheless, a plurality of individual fin-like portions 23 may be formed between the first and the second doped portion 21, 22, forming a plurality of channels. The gate electrode 24 and the insulating material may be formed at first predetermined portions of a plurality of individual fin-like portions 23. Furthermore, the gate electrode 24 and/or the insulating material of individual fin-like portions 23 may form a common gate electrode 24 and a common insulating material for a plurality of individual fin-like portions 23, respectively.

FIG. 3A illustrates a perspective view of an embodiment of the transistor of FIG. 2. On an insulating material 36, which may be an buried oxide layer of a SOI- or a SOS-substrate, a semiconductor material 30 is formed and patterned such, that a first and a second doped portion 31, 32 and a section 33 are formed. In the perspective view of FIG. 3A, a gate insulator material 37 can be seen beneath a gate electrode 34. The gate insulator material 37 encloses the side walls and the top portion of the section 33 in a predetermined first portion and insulates the section 33 from the gate electrode 34. Spacers 35 are arranged at both sides of the gate electrode 34, although only one spacer 35 is illustrated in FIG. 3A for the purpose of showing the gate insulator material 37.

FIG. 3B illustrates a schematic cross sectional view through the transistor of FIG. 3A along the line I-I illustrated in FIG. 2, which is through the first predetermined portion of section 33. As can be seen, the section 33 is formed on top of the insulating material 36. The gate electrode 34 encloses the section 33 and the gate insulator 37 is arranged between the section 33 and the gate electrode 34. The gate electrode 34 is configured to control the conductivity of the semiconductor material 30 within the first predetermined portion of section 33.

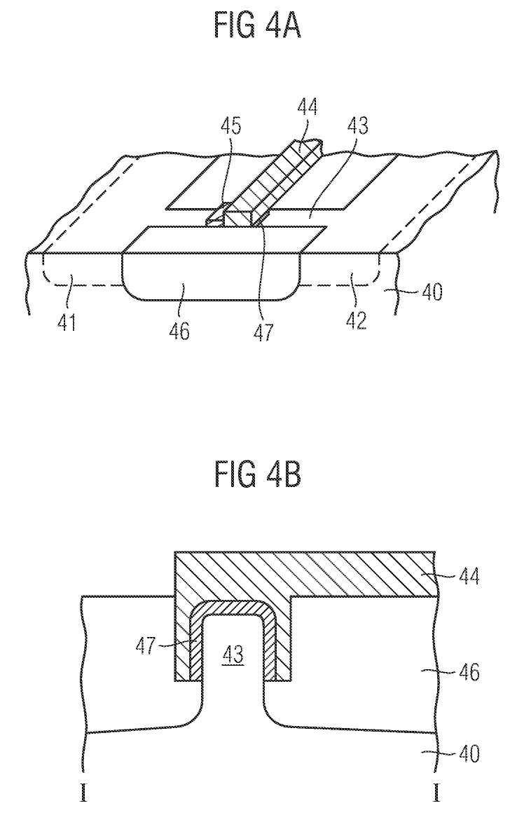

FIG. 4A illustrates another embodiment of the transistor of FIG. 2. In a semiconductor material 40, which may be a bulk semiconductor material like for instance a silicon wafer, a first and a second doped portion 41, 42 and a section 43 are formed. The section 43 has the shape of a ridge and is laterally limited at both sides by an insulating material 46. The insulating material 46 may for instance be a semiconductor oxide or a semiconductor nitride, like for instance silicon oxide or silicon nitride. A gate electrode 44 is formed above side portions and an upper portion of a first predetermined portion of the section 43 and may extend on top of the insulating material 46. Spacers 45 may be formed at side portions of the gate electrode 44 insulating the gate electrode 44 from the semiconductor material 40 at the side portions. A gate insulator material 47 is arranged between the section 43 and the gate electrode 44. Only one spacer 45 is illustrated in FIG. 4A for the purpose of showing the gate insulator material 47.

FIG. 4B illustrates a schematic cross sectional view through the transistor of FIG. 4A along the line I-I illustrated in FIG. 2, which is through the first predetermined portion of section 43. As can be seen, the section 43 is formed as a fin-portion of the semiconductor material 40. The section 43 may have different shapes, like for instance a rectangular shape as illustrated in FIG. 4B, or a triangular shape. The section 43 is partially enclosed by the insulating material 46. The insulating material 46 may insulate individual sections 43 of a plurality of sections 43, as described with respect to FIG. 2. The gate electrode 44 encloses the section 43 partially and extends to a depth smaller or equal to the depth of the section 43, the depth measured from a top surface of the section 43. The gate electrode 44 may be arranged at both sidewalls of the section 43, as illustrated in FIG. 4B, or may be arranged only at one sidewall of the section 43. The gate insulator 47 is arranged between the section 43 and the gate electrode 44. The gate electrode 44 may fill the space between individual sections 43. In this case, the gate insulator 47 may be arranged between the gate electrode 44 and the semiconductor material 40. The gate electrode 44 is configured to control the conductivity of the semiconductor material 40 within the first predetermined portion of section 43.

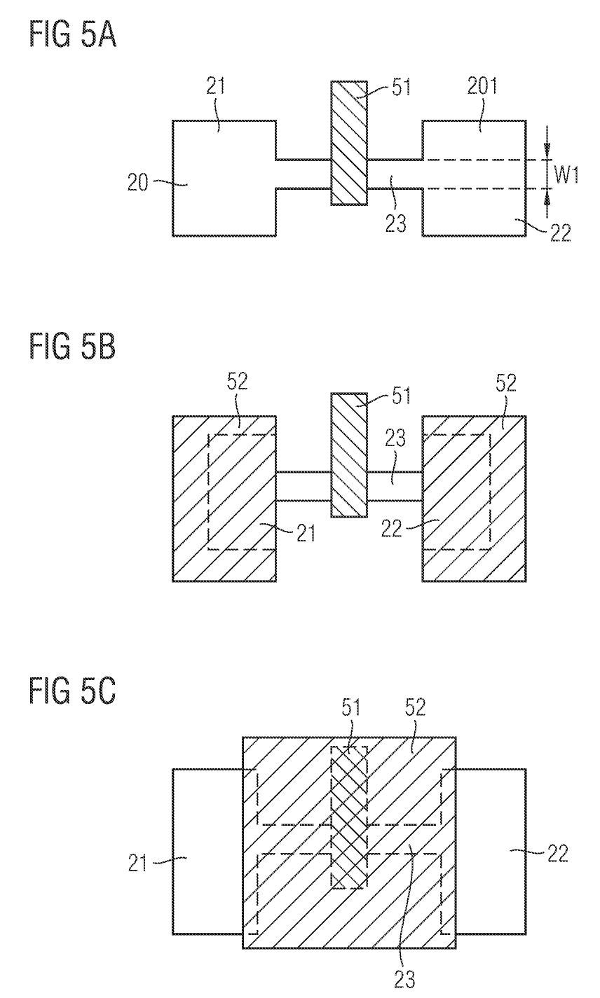

FIGS. 5A to 5C illustrate plan views on embodiments of the described transistor at different processing steps of the described method. First, an active region 201 is defined in a semiconductor material 20. The active region 201 may be defined by patterning the semiconductor material 20, thereby forming at least a section 23 having the shape of a ridge. The section 23 has a width w1. The width w1 may be larger than or equal to 10 nm. The width w1 may be smaller than or equal to 50 nm.

Next, a first cover layer 51 may be formed above the semiconductor material 20, the first cover layer 51 covering at least a first predetermined portion of the section 23. The first cover layer 51 may include different materials or a layer stack of different materials. It may for instance cover other layers formed on top of the semiconductor material 20 within the first predetermined portion, like for instance a gate insulating material, a gate electrode material or a spacer material. The lateral extension of the first cover layer 51 may be larger than the lateral extension of other layers formed on top of the semiconductor material 20 within the first predetermined portion. Furthermore, the cover layer 51 may cover other portions of the active area 201 as well, like for instance portions outside the section 23. Nevertheless, different cover layers having different materials or having different thicknesses may be formed above different portions of the active area 201.

The cover layer 51 may have a thickness of more than or equal to 2 nm. The cover layer may have a thickness of less than or equal to 5 nm. The thickness should be sufficient to prevent diffusion of dopants into the covered semiconductor material 20. Furthermore, the cover layer 51 may serve as a stress liner, inducing a predetermined stress, for instance a tensile stress, into the underlying semiconductor material 20, thereby changing the charge carrier mobility. A SiN layer, for instance, induces a tensile stress. Nevertheless, other materials, like for instance other semiconductor nitrides or oxides, may induce a stress into the underlying materials. In this case the thickness of the cover layer 51 should be larger than 20 nm. It may be smaller than 50 nm, wherein the thickness is limited by the lateral space of the section 23 to neighboring sections 23 or to other neighboring structures.

As described with respect to FIG. 1A, a further thin cover layer (not illustrated) may be formed above the semiconductor material 20, the further cover layer covering at least the section 23 outside the first predetermined portion. The further cover layer may be formed after forming the first cover layer 51. The further cover layer may be formed, for instance, by a nitridation process forming a semiconductor nitride, like for example SiN. The nitridation process may be carried out by a predetermined temperature, like for instance 700° C., wherein the thickness of the resulting further cover layer depends on the used temperature and is self-limited. The thickness of the further cover layer may be one monolayer or more. The thickness of the further cover layer may be 2 nm or less.

A gas-phase doping (GPD-) process is carried out to form doped regions within the active region 201. The GPD-process may use AsH₃ or PH₃ as gases providing dopants for n-type doping or BH₃ as gas providing dopants for p-type doping. Nevertheless, other gases providing dopants may be used. The molecules of the doping gas dissociate at surfaces being exposed to the gas thereby releasing dopants. The dopants may diffuse into the semiconductor material not being covered by the first cover layer 51. The cover layer 51 limits the diffusion of dopants such that the conduction type of the underlying material is not changed. A first and a second doped region 21, 22 are formed within the semiconductor material 20 in that portions which are not covered by the cover layer 51. The resulting structure is illustrated in FIG. 5A.

The GPD-process may be carried out by temperatures between 400° C. and 900° C., for example between 600° C. and 700° C., for a predetermined time period, like for instance 30 minutes. The GPD-process may be carried out as a batch process in a tube for a plurality of carriers including the semiconductor material 20 or may be carried out as a single carrier process in a respective tool. The thermal budget, that is the time-temperature effect on the semiconductor material, may be limited by the rounding effect of hydrogen, which may be contained in the gas, on the semiconductor material. This is for instance of concern, if silicon is used as the semiconductor material formed on an insulating material, like it is the case for a SOI-substrate.

The resulting concentration of dopants within the semiconductor material may be controlled by the concentration and the pressure of the gas and the used temperature and the time of the GPD-process. The maximum concentration of dopants within the semiconductor material should be as high as possible, like for instance higher than 1·10²⁰ cm⁻³.

Accordingly, a very good homogeneity of dopant concentration across the semiconductor material 20, especially within the section 23, may be accomplished. The difference between the maximum concentration at the surface of the semiconductor material and the minimum concentration found in the center of the section 23 may be around a factor 2 or may be less. Furthermore, no problems with shadowing effects of neighboring structures occur and the semiconductor material 20 will not get amorphous.

If a further thin cover layer is formed above the semiconductor material 20 of the section 23 as described above, the maximum dopant concentration and the homogeneity of the dopant concentration within the semiconductor material 20 may be controlled. The doping process may then be controlled rather by the diffusion coefficient of the dopants through the further thin cover layer than by the amount of dopants released from the gas.

In order to increase the diffusion of dopants into the semiconductor material and in order to limit the diffusion of dopants into the predetermined portion of section 23, which is covered by the cover layer 51, the diffusion coefficient of the dopants may be increased in the semiconductor material 20 outside the predetermined portion by creating additional, non-intrisic, lattice-defects like interstitials. For instance, a process inducing crystal damages or lattice imperfections may be carried out before carrying out the gas-phase doping. By way of example, an ion-implantation process with predetermined species may be carried out after covering the predetermined portion of the section 23 and before carrying out the gas-phase doping. The predetermined species, like for instance C, F, Si, Ge or dopants like As, P or B, create lattice imperfections within the active region 201 outside the predetermined portion. The lattice imperfections enhance the diffusion of dopants, whereas the diffusion of dopants is limited by the intrinsic diffusion coefficient in the predetermined portion having no additional lattice imperfections. The implanted species, like for instance C, may remain within the semiconductor material. The implanted species, like for instance F, may be implanted into a material lying beneath the semiconductor material 20, like for instance the insulating material 36 as illustrated in FIG. 3A.

A second cover layer 52 may be formed above second predetermined portions of the active region 201, as is illustrated by way of example in FIG. 5B or 5C. The first cover layer 51 may remain at the first predetermined portions as illustrated in FIGS. 5B and 5C or may be removed, if the second predetermined portions include the first predetermined portion.

In the example illustrated in FIG. 5B, the first and the second doped region 21, 22 are covered by the second cover layer. Subsequently, a further doping process, for instance a second gas-phase doping process, may be carried out, further increasing the dopant concentration within the semiconductor material 20 of section 23 outside the first predetermined portion. Thus, for instance, heavily doped source and drain extension regions may be formed within the fin-portion.

In the example illustrated in FIG. 5C, at least the section 23 of the active region 201 is covered by the second cover layer 52. Subsequently, a further doping process, for instance a second gas-phase doping process or an ion-implantation process, may be carried out, further increasing the dopant concentration within the semiconductor material 20 outside of section 23. Thus, for instance, heavily doped source and drain regions may be formed.

Nevertheless, it is possible to form the second cover layer 52 and to carry out a further doping process before carrying out the first gas-phase doping process.

Furthermore, it is possible to carry out an additional process, like for instance a selective epitaxy process before carrying out the first gas-phase doping process. Such an epitaxy process is selective, since a layer growth takes place only on a monocrystalline semiconductor material. To put it more precisely, a selective epitaxy process illustrates a net growth rate larger than zero on a monocrystalline semiconductor material and a net growth rate equal to zero on other materials. As a consequence, the semiconductor material grows only on the monocrystalline surface regions.

The epitaxy process may include partially removing the semiconductor material 20 of the active region 201 and forming a semiconductor material at the place of the removed material. At least the first predetermined portion of the section 23, that is the channel, may be not removed. The semiconductor material 20 of the active region 201 outside the first predetermined portion may be removed partially and may be replaced by the new semiconductor material formed by the epitaxy process. The new semiconductor material may be formed by a doped epitaxy process, that is an epitaxy process using materials having dopants, and may have a predetermined conduction type, which may for instance be opposite to the conduction type of the removed semiconductor material 20. The new semiconductor material may be formed by an epitaxy process using materials not having dopants. The new semiconductor material may be the same semiconductor material as the original semiconductor material, like for instance silicon, or may be another semiconductor material, like for instance SiGe or Si:C, that is silicon containing carbon additive, for example at most 3 at-% carbon.

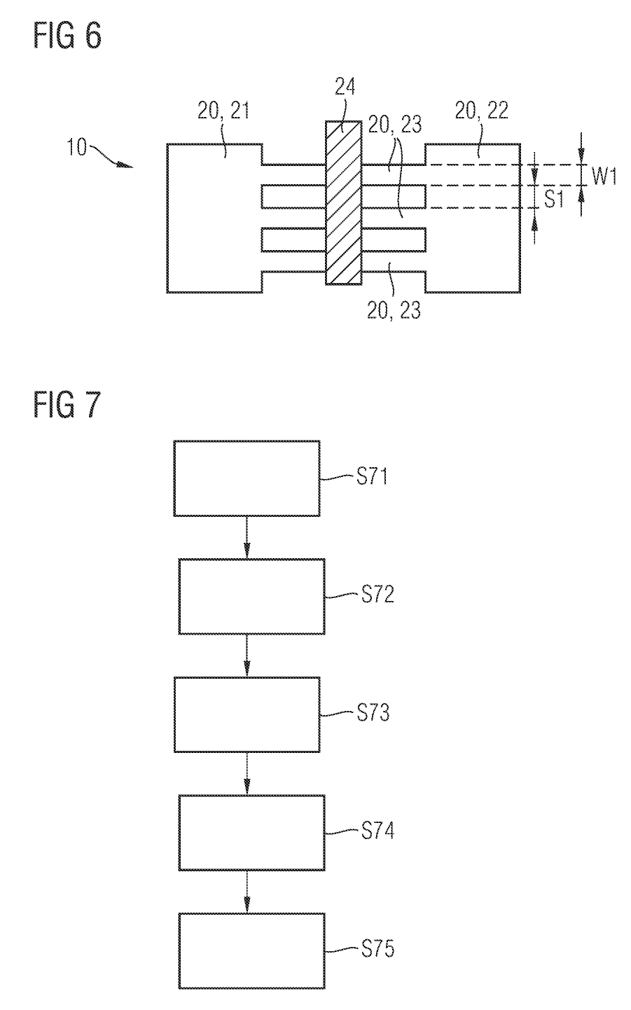

FIG. 6 illustrates a plan view on an embodiment of a transistor 10 having a plurality of fin-like portions 23. The transistor 10 includes an active region formed within a semiconductor material 20 and includes a first and a second doped region 21, 22 and a plurality of sections 23. Each section 23 has the shape of a ridge and connects the first and the second doped region 21 and 22. Each section 23 has a width w1 and a distance s1 to a neighboring section 23. The distance s1 may for instance be around 100 nm. The transistor 10 further includes a gate insulating material adjacent to predetermined channel regions within the semiconductor material of sections 23, and a plurality of gate electrodes 24, wherein each gate electrode is adjacent to the gate insulating material on at least one section 23. FIG. 6 illustrates for example a common gate electrode 24 adjacent to the gate insulating material on all sections 23.

FIG. 7 illustrates a flow diagram of an embodiment of a method for manufacturing an integrated circuit. First, at least one first active region in a semiconductor material is defined (S71). The first active region includes a first section having the shape of a ridge. A plurality of first active regions each first active region having a first section having the shape of a ridge may be defined.

At least one second active region in a semiconductor material is defined (S72). The second active region includes a second section having the shape of a ridge. A plurality of second active regions each second active region having a second section having the shape of a ridge may be defined.

The semiconductor material may be the same for the first and the second active region and may be similar to the substrate defined above. Nevertheless, the semiconductor material of the first active region may be another than that of the second active region.

The active regions may be defined by patterning the semiconductor material, like for instance by etching. Each active region includes at least one section having the shape of a ridge. These sections are also called fin-portions. In the fin-portions, a current path or channel between a source region and a drain region of a transistor is to be formed, wherein the conductivity of the current path may be controlled by a gate electrode. At least one active region may include a plurality of fin-portions.

A first cover layer may be formed above the semiconductor material of a first predetermined portion of the first section, and a second cover layer may be formed above the semiconductor material of a first predetermined portion of the second section (S73). The first and the second cover layer may include the same materials and/or may have the same thickness. The first predetermined portions of the first and the second section include that part of the first and the second section, where the channel is to be formed. The first and the second cover layer may be formed as described above. Nevertheless, the first and the second cover layer may include different materials and/or may have different thicknesses.

Next, a source and a drain region in the first active region are provided, wherein this process includes carrying out a first gas-phase doping (S74). The source and the drain region may be provided as described above.

Next, a source and a drain region are provided in the second active region (S75). This may be accomplished by carrying out a process including a gas-phase doping or by carrying out another process, like for example a selective epitaxy process using materials having dopants.

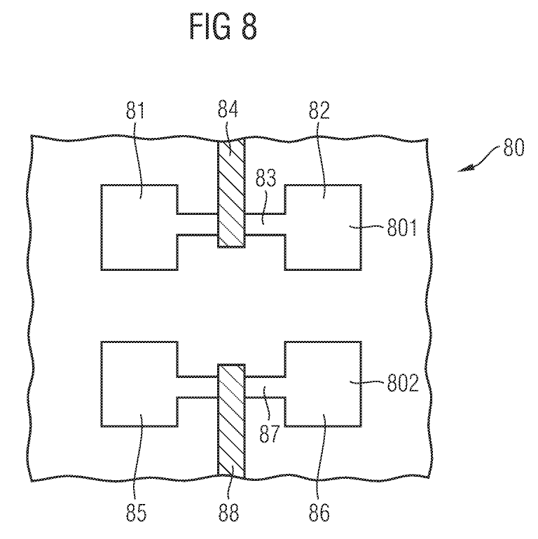

FIG. 8 illustrates a plan view on an embodiment of an integrated circuit 80 having a first and a second transistor. The first transistor includes a first active region 801 defined in a first semiconductor material. The first active region 801 includes a source and a drain region 81, 82 and a first section 83 having the shape of a ridge. The first transistor includes a first gate electrode 84 formed above a predetermined portion of the section 83. A first gate insulator material is arranged between the semiconductor material of the section 83 and the first gate electrode 84. Spacers (not illustrated) may be arranged at the sides of the gate electrode 84.

The second transistor includes a second active region 802 defined in a second semiconductor material. The second semiconductor material may be the same or a different material like the first semiconductor material. The second active region 802 includes a source and a drain region 85, 86 and a second section 87 having the shape of a ridge. The second transistor includes a second gate electrode 88 formed above a predetermined portion of the section 87. A second gate insulator material is arranged between the semiconductor material of the section 87 and the second gate electrode 88. The second gate insulator material may be the same as the first gate insulator material or may be a different material. Spacers (not illustrated) may be arranged at the sides of the gate electrode 88. The source and the drain region of the first active area 801 may have the same or a different conduction type like the source and the drain region of the second active area 802. The source and the drain region 81, 82 and/or the section 83 of the first active area 801 may have the same dimensions as the source and the drain region 85, 86 and the section 87 of the second active area 802, respectively.

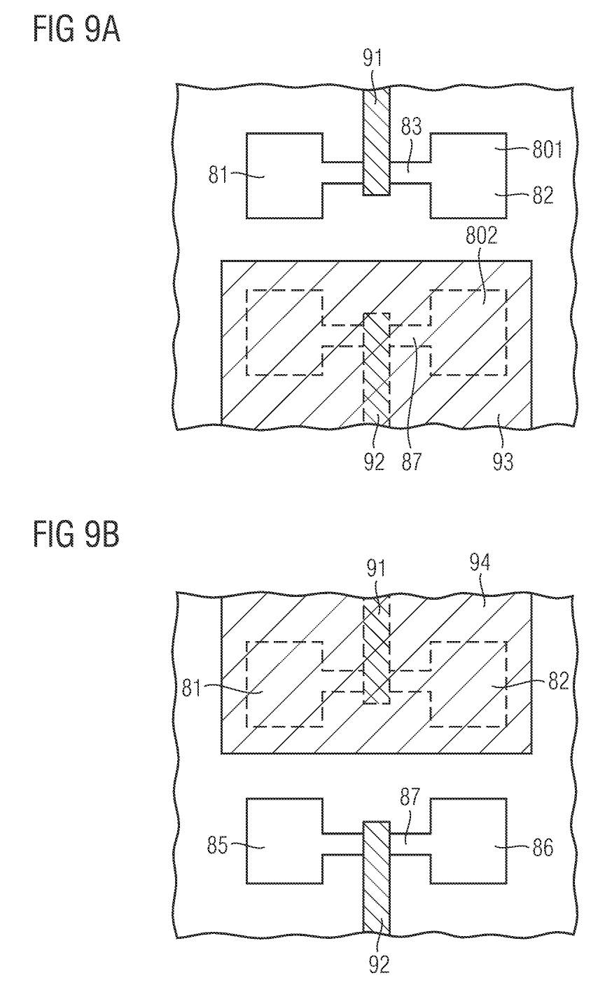

FIGS. 9A and 9B illustrate plan views on an embodiment of the described integrated circuit at different processing steps of the described method. First, the first and the second active region 801, 802 are defined as described above. A first cover layer 91 is formed above a first predetermined portion of the section 83, and a second cover layer 92 may be formed above a first predetermined portion of the section 87. Nevertheless, the second cover layer 92 may as well be formed later. The first and the second cover layer may be formed of the same or of different materials or layer stacks and may be formed having the same or different thicknesses. The first and the second cover layer 91, 92 may include the first and the second gate insulator material and the first and the second gate electrode 84, 88, respectively. Next, a third cover layer 93 may be formed above the second active area 802. A fifth cover layer (not illustrated) may be formed above the first active area 801. The fifth cover layer may be formed at least above the section 83 outside the first predetermined portion. The fifth cover layer may include the same material as the first cover layer 91 or may include other materials. It retards the diffusion of dopants into the semiconductor material as described with respect to FIG. 1A.

The source and the drain region 81, 82 of the first transistor are provided in the first active area 801 by carrying out a process having a first gas-phase doping process as described above. The first gas-phase doping process uses a gas having dopants of an desired conduction type. The process for providing the source and the drain region 81, 82 may further include other doping processes as described above. The resulting structure is illustrated in FIG. 9A.

Next, the third cover layer 93 may be partially removed, for instance by a wet or a dry etching process, and a fourth cover layer 94 is formed above the first active region 801. If the second cover layer 92 is not yet formed, it is formed above a first predetermined portion of the section 87. If the third cover layer 93 is not removed from the first predetermined portion of the section 87, it may serve as the second cover layer 92. A sixth cover layer (not illustrated) may be formed above the second active area 802. The sixth cover layer may be formed at least above the section 87 outside the second predetermined portion. The sixth cover layer may include the same material as the second cover layer 92 or may include other materials. It retards the diffusion of dopants into the semiconductor material as described with respect to FIG. 1A.

The source and the drain region 85, 86 of the second transistor are provided by a process which may include a second gas-phase doping process or may include another doping process, like for instance a selective epitaxy process using materials having dopants. The resulting structure is illustrated in FIG. 9B.

The fourth cover layer 94 may be removed subsequently. The first and the second cover layer 91, 92 may be removed or may remain above the first predetermined portions as well as the fifth and the sixth cover layer. At least one of the cover layers may be configured to induce a predetermined stress into the underlying semiconductor material.

The third and the fourth cover layer may be formed of the same materials and/or with the same thicknesses as the first and the second cover layer, respectively. Nevertheless, they may be formed of other materials or with other thicknesses, as long as they prevent an undesired doping or processing of the underlying regions.

As described above, a conduction type of the source and the drain region 81, 82 of the first transistor may be a first conduction type which may be different from a second conduction type of the source and the drain region 85, 86 of the second transistor. The first conduction type may be n-type, and the second conduction type may be p-type.

The transistor fabricated by the described method may be a SOI-FinFet, a local SOI/bulk-FinFet or a bulk-FinFet. The integrated circuit fabricated by the described method may for instance be a DRAM with a high current flow per area or a capacitor-less DRAM or another memory device or a logic circuitry or a processor. The fabricated transistors or integrated circuits may be used in low-leakage devices, logic devices, high-voltage devices, high-speed devices, low-standby-power devices or battery-operated or mobile systems, like for instance in a mobile RAM.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adoption or variations of the specific embodiments discussed herein. Therefore it is intended that this invention be limited only by the claims and the equivalents thereof.

What is claimed is:

1. A method making an integrated circuit comprising:
providing a substrate comprising at least one fin of a semiconductor material; and
carrying out a gas-phase doping of the at least one fin.

2. The method of claim 1, further comprising providing a first cover layer above a predetermined section of the at least one fin before carrying out the gas-phase doping.

3. The method of claim 2, comprising providing a second cover layer above the semiconductor material outside the predetermined section of the at least one fin before carrying out the gas-phase doping, wherein a diffusion coefficient of dopants through the second cover layer is higher than a diffusion coefficient of dopants through the first cover layer.

4. The method of claim 3, wherein the first and the second cover layer comprise the same materials, and wherein the thickness of the second cover layer is smaller than the thickness of the first cover layer.

5. The method of claim 1, comprising wherein the dopant concentration within the fin is higher than 1·1020 cm−3 after carrying out the gas-phase doping.

6. The method of claim 1, comprising wherein the difference between the maximum and the minimum of dopant concentration within the fin is not more than factor 2.

7. A method comprising:
providing a substrate comprising at least one fin of a semiconductor material; and
carrying out a gas-phase doping of the at least one fin.

8. The method of claim 7, further comprising providing a first cover layer above a predetermined section of the at least one fin before carrying out the gas-phase doping.

9. The method of claim 8, comprising providing a second cover layer above the semiconductor material outside the predetermined section of the at least one fine before carrying out the gas-phase doping, wherein the diffusion coefficient of dopants through the second cover layer is higher than the diffusion coefficient of the dopants through the first cover layer.

10. The method of claim 9, wherein the first and the second cover layer comprise the same materials, and wherein the thickness of the second cover layer is smaller than the thickness of the first cover layer.

11. The method of claim 7, comprising forming the fin on an insulating material.7

12. The method of claim 7, comprising wherein the fin has a width not more than 50 nm.

13. The method of claim 7, comprising wherein the dopant concentration within the fin is higher than 1·1020 cm−3 after carrying out the gas-phase doping.

14. The method of claim 7, comprising wherein the difference between the maximum and the minimum of dopant concentration within the fin is not more than factor 2.

15. The method of claim 7, comprising creating lattice imperfections within the fin before carrying out the gas-phase doping.

16. The method of claim 7, comprising creating the lattice imperfections by carrying out an ion-implantation method with a predetermined species before carrying out the gas-phase doping.

17. A method for manufacturing a transistor, comprising:
defining an active region in a semiconductor material, the active region comprising a section having the shape of a ridge;
covering a first predetermined portion of the section of the active region with a first cover layer; and
providing a source and a drain region in the active region, wherein providing the source and the drain region comprises carrying out a gas-phase doping process.

18. The method of claim 17, wherein the first cover layer comprises a gate insulating material and a gate electrode of the transistor.

19. The method of claim 17, comprising wherein providing the source and the drain region further comprises providing a second cover layer above second predetermined portions of the active region before carrying out a further doping process.

20. The method of claim 17, comprising creating lattice imperfections within the active region before carrying out the gas-phase doping process.

21. The method of claim 20, comprising creating the lattice imperfections by carrying out an ion-implantation method with a predetermined species after covering the first predetermined portion with the first cover layer and before carrying out the gas-phase doping.

22. The method of claim 21, comprising wherein the implanted species remain within the active region.

23. The method of claim 17, comprising defining the active region in a semiconductor material formed on an insulating material.

24. The method of claim 17, comprising forming the active region as a part of a semiconductor substrate and wherein the section having the shape of a ridge is laterally delimited by an insulating material.

25. The method of claim 17, wherein the active region comprises a plurality of sections having the shape of a ridge.

26. The method of claim 17, comprising configuring the first cover layer to induce a stress into the underlying semiconductor material.

27. The method of claim 17, comprising providing a third cover layer above the semiconductor material outside the first predetermined portion of the section of the active region before carrying out the gas-phase doping process, wherein the diffusion coefficient of dopants through the third cover layer is higher than the diffusion coefficient of the dopants through the first cover layer.

28. The method of claim 27, wherein the first and the third cover layer comprise the same materials, and wherein the thickness of the third cover layer is smaller than the thickness of the first cover layer.

29. A method of manufacturing an integrated circuit comprising:
defining at least one first active region in a semiconductor material, the first active region comprising a first section having the shape of a ridge;
defining at least one second active region in a semiconductor material, the second active region comprising a second section having the shape of a ridge;
covering a first predetermined portion of the first section with a first cover layer and covering a first predetermined portion of the second section with a second cover layer;
providing a source and a drain region in the first active region, wherein providing the source and the drain region comprises carrying out a first gas-phase doping process; and
providing a source and a drain region in the second active region.

30. The method of claim 29, comprising wherein the conduction type of the source region and the drain region in the first active region is a first conduction type different from the conduction type of the source region and the drain region in the second active region which is a second conduction type.

31. The method of claim 30, comprising:
the first conduction type is n-type and the second conduction type is p-type;
the p-type source and drain regions are formed by a method comprising carrying out a selective epitaxy of a p-type semiconductor material.

32. The method of claim 29, comprising wherein the source region and the drain region in the second active region are provided by a process comprising a second gas-phase doping process.

33. The method of claim 29, comprising covering the second active region by a third cover layer during providing the source and the drain region of the first active region and covering the first active region by a fourth cover layer during providing the source and the drain region of the second active region.

34. The method of claim 33, comprising wherein at least one of the cover layers covering the first or the second active region is configured to induce a stress into the underlying semiconductor material.

35. The method of claim 29, comprising providing a fifth cover layer above the semiconductor material outside the first predetermined portion of the first section before carrying out the first gas-phase doping process, wherein the diffusion coefficient of dopants through the fifth cover layer is higher than the diffusion coefficient of the dopants through the first cover layer.

36. The method of claim 35, wherein the first and the fifth cover layer comprise the same materials, and wherein the thickness of the fifth cover layer is smaller than the thickness of the first cover layer.

37. The method of claim 32, comprising providing a sixth cover layer above the semiconductor material outside the second predetermined portion of the second section before carrying out the second gas-phase doping process, wherein the diffusion coefficient of dopants through the sixth cover layer is higher than the diffusion coefficient of the dopants through the second cover layer.

38. The method of claim 37, wherein the second and the sixth cover layer comprise the same materials, and wherein the thickness of the sixth cover layer is smaller than the thickness of the second cover layer.

39. A transistor comprising:
an active region in a semiconductor material, the active region comprising a section having the shape of a ridge, wherein the difference between a maximum and a minimum dopant concentration within the section outside a predetermined portion is not more than factor 2.

40. The transistor of claim 39, comprising wherein the maximum concentration of dopants within the section outside the predetermined portion is higher than 1·1020 cm−3.

41. The transistor of claim 39, comprising wherein the section has a width of not more than 50 nm.

42. The transistor of claim 39, comprising wherein the section is formed on an insulating material.

43. The transistor of claim 39, wherein the active region comprises a plurality of sections having the shape of a ridge.

44. The transistor of claim 39, comprising wherein each section has a width of not more than 50 nm and wherein two neighboring sections of the plurality of sections have a distance to each other of not more than 100 nm.
